(19) United States
(12) Patent Application Publication
(10) Pub. No.: US 2025/0366232 A1
(43) Pub. Date: Nov. 27, 2025

(54) IMAGE SENSOR

(71) Applicant: Samsung Electronics Co., Ltd., Suwon-si (KR)

(72) Inventor: Haewon Lee, Suwon-si (KR)

(21) Appl. No.: 19/097,937

(22) Filed: Apr. 2, 2025

(30) Foreign Application Priority Data
May 21, 2024 (KR) 10-2024-0065860

(51) Int. Cl. H10F 39/00; H10F 39/18

(52) U.S. Cl. CPC H10F 39/80373; H10F 39/014; H10F 39/018; H10F 39/182; H10F 39/809

(57) ABSTRACT

An image sensor includes a first semiconductor substrate, a photoelectric conversion region located within the first semiconductor substrate, a floating diffusion region located within the first semiconductor substrate and storing charges transferred from the photoelectric conversion region, a first transfer transistor including a first transfer gate having a vertical form and disposed to be apart from the floating diffusion region in a horizontal direction and electrically connecting the photoelectric conversion region to the floating diffusion region, and a second transfer transistor including a second transfer gate located between the first transfer gate and the floating diffusion region and having a form different from the form of the first transfer gate and electrically connecting the first transfer transistor to the floating diffusion region.

### CROSS-REFERENCE TO RELATED APPLICATION

This application is based on and claims priority under 35 USC § 119 to Korean Patent Application No. 10-2024-0065860, filed on May 21, 2024, in the Korean Intellectual Property Office, the disclosure of which is incorporated by reference herein in its entirety.

### BACKGROUND

The inventive concept relates to an image sensor, and more particularly, to an image sensor including a photodiode.

Image sensors are devices that convert optical image signals into electrical signals. Image sensors include a plurality of pixels, each of which receives incident light and converts the received light into an electrical signal, and includes a photodiode region. Generally, a unit pixel may include a light sensing element, such as a photodiode and a plurality of pixel transistors. Here, the pixel transistors may include, for example, a transfer transistor, a reset transistor, a source follower transistor, and a select transistor, and the transfer transistor connects a photodiode to a floating diffusion region.

### SUMMARY

Aspects of the inventive concept provide an image sensor having improved performance through pixels with a high conversion gain function.

The benefits of the inventive concept are not limited to the benefits mentioned above, and other benefits not mentioned will be clearly understood by those skilled in the art from the description below.

According to an aspect of the inventive concept, an image sensor includes a first semiconductor substrate, a photoelectric conversion region located within the first semiconductor substrate, a floating diffusion region located within the first semiconductor substrate and storing charges transferred from the photoelectric conversion region, a first transfer transistor including a first transfer gate having a vertical form and disposed to be apart from the floating diffusion region in a horizontal direction and electrically connecting the photoelectric conversion region to the floating diffusion region, and a second transfer transistor including a second transfer gate located between the first transfer gate and the floating diffusion region and having a form different from the form of the first transfer gate and electrically connecting the first transfer transistor to the floating diffusion region.

According to another aspect of the inventive concept, an image sensor includes a first semiconductor substrate including a first surface and a second surface opposite to the first surface, a photoelectric conversion region located within the first semiconductor substrate, a floating diffusion region located within the first semiconductor substrate and storing charges transferred from the photoelectric conversion region, a first transfer gate in the form of a vertical gate disposed to be apart from the floating diffusion region in a horizontal direction and extending into the first semiconductor substrate in a vertical direction, and a second transfer gate in the form of a planar gate located between the first transfer gate and the floating diffusion region on the first surface.

According to another aspect of the inventive concept, an image sensor includes a first stack including a first semiconductor substrate including a first surface and a second surface opposite to the first surface, a photoelectric conversion region located within the first semiconductor substrate, a floating diffusion region located within the first semiconductor substrate and storing charges transferred from the photoelectric conversion region, a first transfer gate having a vertical form and disposed to be apart from the floating diffusion region in a horizontal direction, and a second transfer gate located between the first transfer gate and the floating diffusion region and having a form different from the form of the first transfer gate, a second stack including a second semiconductor substrate including a first surface and a second surface opposite to the first surface and a pixel gate disposed on the first surface or the second surface of the second semiconductor substrate and electrically connected to the floating diffusion region, and a third stack attached to the second stack, the third stack including a logic transistor providing a signal to the pixel gate, the first transfer gate, and the second transfer gate.

### BRIEF DESCRIPTION OF THE DRAWINGS

Embodiments will be more clearly understood from the following detailed description taken in conjunction with the accompanying drawings in which:

FIG. 1 is a perspective view schematically illustrating an image sensor according to embodiments;

FIG. 2 is a layout diagram illustrating an image sensor corresponding to one pixel in FIG. 1;

FIG. 3 is a cross-sectional view taken along line A-A′ in FIG. 2;

FIG. 4 is an enlarged cross-sectional view of region CX1 of FIG. 3;

FIG. 5 is an equivalent circuit diagram of a pixel of an image sensor according to embodiments;

FIGS. 6A to 6C are timing diagrams illustrating an operation of a unit pixel of FIG. 5;

FIGS. 7 to 13 are cross-sectional views illustrating a method of manufacturing an image sensor, according to embodiments;

FIG. 14 is a layout diagram illustrating an image sensor according to embodiments;

FIG. 15 is a cross-sectional view taken along line A-A′ of FIG. 14;

FIG. 16 is a layout diagram illustrating an image sensor according to embodiments; and

FIG. 17 is a block diagram illustrating a configuration of an image sensor according to an embodiment.

### DETAILED DESCRIPTION OF THE EMBODIMENTS

Hereinafter, embodiments of the inventive concept are described in detail with reference to the accompanying drawings. The same reference numerals are used for the same components in the drawings, and redundant descriptions thereof are omitted.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

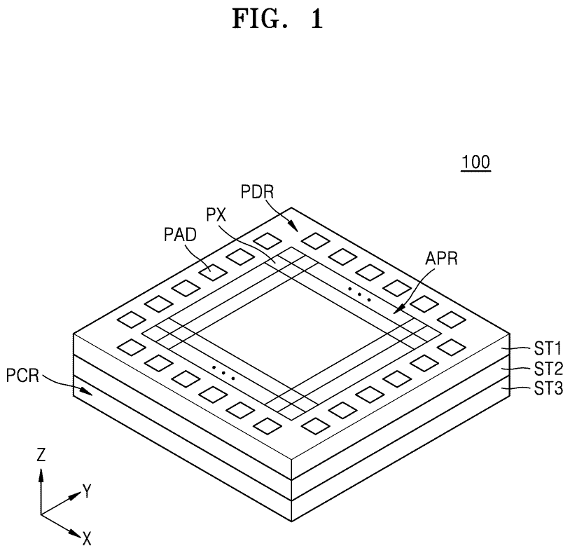

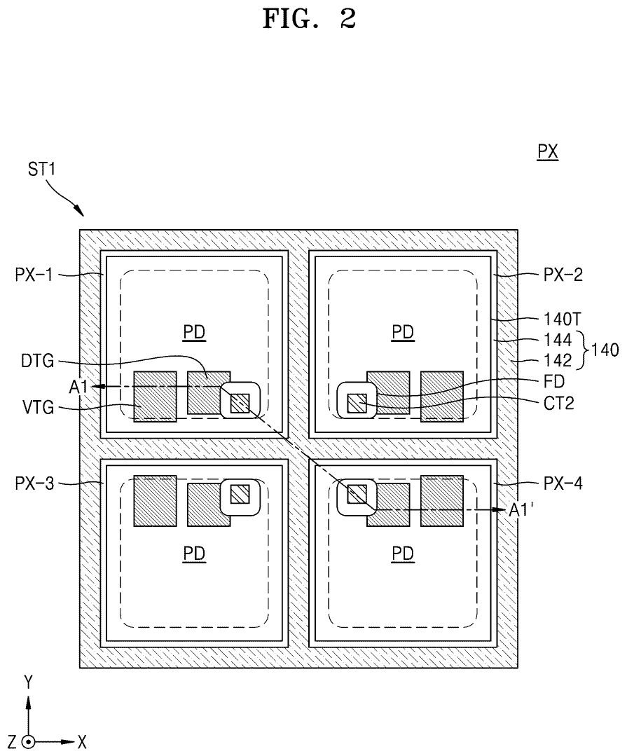

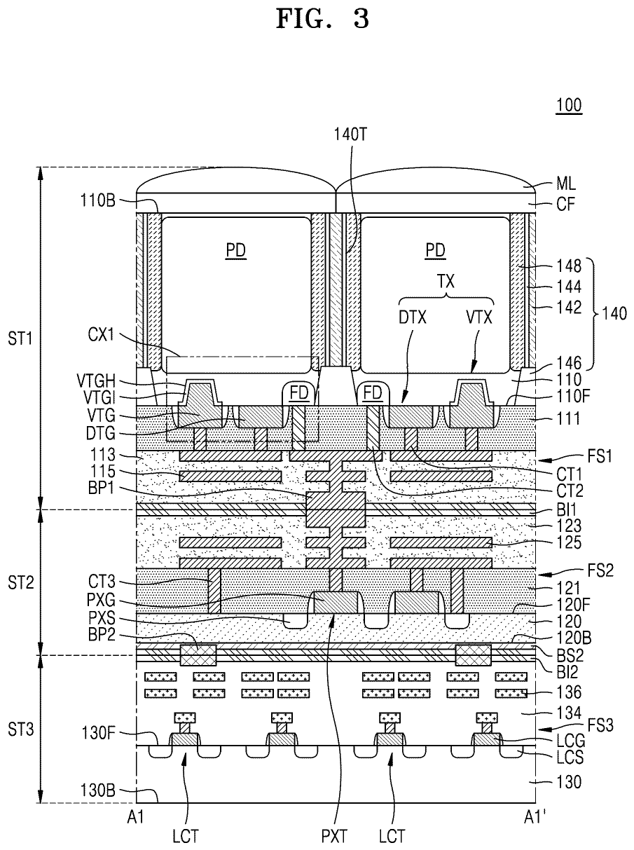

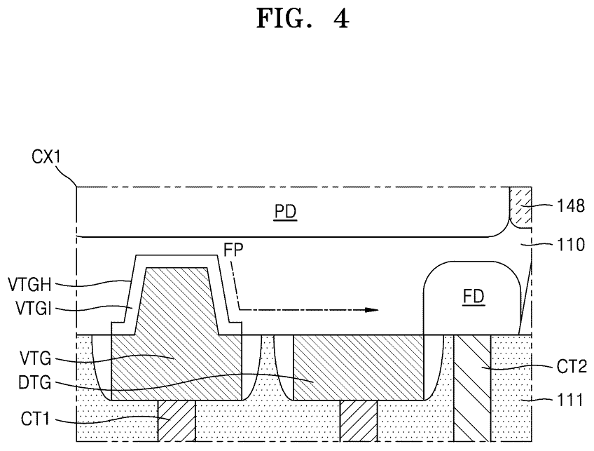

FIG. 1 is a perspective view schematically illustrating an image sensor 100 according to embodiments. FIG. 2 is a layout diagram illustrating the image sensor 100 corresponding to one pixel PX in FIG. 1. FIG. 3 is a cross-sectional view taken along line A-A′ in FIG. 2. FIG. 4 is an enlarged cross-sectional view of region CX1 of FIG. 3.

Referring to FIGS. 1 to 4, the image sensor 100 may be a stacked image sensor in which a first stack ST1, a second stack ST2, and a third stack ST3 are stacked in a vertical direction.

An active pixel region APR may be located in the center of the image sensor 100, and a plurality of pixels PX may be located in the active pixel region APR. The pixels PX may be a region that receives light from the outside of the image sensor 100 and converts the received light into an electrical signal. The pixels PX may be arranged in the first stack ST1 and the second stack ST2. For example, a photoelectric conversion region PD for receiving external light may be located in the first stack ST1, and transistors constituting a pixel circuit for converting photocharges accumulated in the photoelectric conversion region PD into electrical signals may be located in the second stack ST2.

A pad region PDR may be disposed on at least one side of the active pixel region APR, for example, on four sides of the active pixel region APR in a plan view. A plurality of pads PAD may be located in the pad region PDR and may be configured to transmit and receive electrical signals to and from an external device, etc.

A peripheral circuit region PCR may include a logic circuit block and/or a memory device. For example, the logic circuit block may include a plurality of logic transistors LCT and may provide a constant signal to each pixel PX of the active pixel region APR or control an output signal in each pixel PX. For example, the logic transistors LCT may include at least one of a row decoder, a row driver, a column decoder, a timing generator, a correlated double sampler CDS, an analog-to-digital converter, and an input/output (I/O) buffer.

The active pixel region APR may include a plurality of pixels PX, and a plurality of photoelectric conversion regions PD may be located within the pixels PX, respectively. In the active pixel region APR, the pixels PX may be aligned in columns and rows in a first direction X parallel to an upper surface of a first semiconductor substrate 110 and a second direction Y perpendicular to the first direction and parallel to the upper surface of the first semiconductor substrate 110 in a matrix form. Some of the pixels PX may be optical black pixels (not shown). The optical black pixel may function as a reference pixel for the active pixel region APR and may perform a function to automatically correct dark signals.

In embodiments, as illustrated in FIG. 2, a first pixel PX-1, a second pixel PX-2, a third pixel PX-3, and a fourth pixel PX-4 may be arranged in a matrix form. Each of the first to fourth pixels PX-1, PX-2, PX-3, and PX-4 in the first stack ST1 may have the photoelectric conversion region PD and a floating diffusion region FD.

The first stack ST1 may include a first semiconductor substrate 110 having a front surface 110F and a rear surface 110B, a photoelectric conversion region PD and a floating diffusion region FD formed inside the first semiconductor substrate 110, a first transfer gate VTG disposed on the front surface 110F of the first semiconductor substrate 110, a second transfer gate DTG and a first front structure FS1, and a color filter CF and a microlens ML disposed on the rear surface 110B of the first semiconductor substrate 110.

The second stack ST2 may include a second semiconductor substrate 120 having a front surface 120F and a rear surface 120B, a pixel transistor PXT and a second front structure FS2 disposed on the front surface 120F of the second semiconductor substrate 120, and a rear structure BS2 disposed on the rear surface 120B of the second semiconductor substrate 120.

The third stack ST3 may include a third semiconductor substrate 130 having a front surface 130F and a logic transistor LCT and a third front structure disposed on the front surface 130F of the third semiconductor substrate 130.

The second stack ST2 is located between the first stack ST1 and the third stack ST3. For example, the second front structure FS2 of the second stack ST2 may be disposed to face the front structure FS1 of the first stack ST1, and the rear structure BS2 of the second stack ST2 may be disposed to face the third front structure FS3 of the third stack ST3.

In embodiments, the first to third semiconductor substrates 110, 120, and 130 may include a P-type semiconductor substrate. For example, at least one of the first to third semiconductor substrates 110, 120, and 130 may include a P-type silicon substrate. In embodiments, at least one of the first to third semiconductor substrates 110, 120, and 130 may include a P-type bulk substrate and a P-type or N-type epitaxial layer grown thereon, and in other embodiments, at least one of the first to third semiconductor substrates 110, 120, and 130 may include an N-type bulk substrate and a P-type or N-type epitaxial layer grown thereon.

A pixel isolation structure 140 may be located within the first semiconductor substrate 110 of the first stack ST1. The pixels PX may be defined by the pixel isolation structure 140. The pixel isolation structure 140 may include a conductive layer 142, an insulating liner 144, and an upper insulating layer 146. The conductive layer 142 may be located inside a pixel trench 140T passing through the first semiconductor substrate 110. The insulating liner 144 may be disposed on an inner wall of the pixel trench 140T passing through the first semiconductor substrate 110 and may be located between the conductive layer 142 and the first semiconductor substrate 110. The upper insulating layer 146 may be located within a portion of the pixel trench 140T adjacent to the front surface 110F of the first semiconductor substrate 110.

In embodiments, the pixel isolation structure 140 may pass through the first semiconductor substrate 110. For example, the pixel isolation structure 140 may be front-side deep trench isolation (FDTI). Unlike shown, the pixel isolation structure 140 may not pass through the first semiconductor substrate 110. For example, the pixel isolation structure 140 may be back-side deep trench isolation (BDTI).

In embodiments, the conductive layer 142 may include at least one of doped polysilicon, metal, metal silicide, metal nitride, or a metal-containing layer. The insulating liner 144 may include an insulating material, such as silicon oxide, silicon nitride, or silicon oxynitride. The upper insulating layer 146 may include an insulating material, such as silicon oxide, silicon nitride, or silicon oxynitride.

The photoelectric conversion regions PD may be located within the first stack ST1 within the pixels PX, respectively. The photoelectric conversion region PD may be a region within the first semiconductor substrate 110 doped with n-type impurities. For example, the photoelectric conversion region PD may have a potential gradient due to a difference in impurity concentration between upper and lower portions thereof. Alternatively, the photoelectric conversion region PD may be formed by stacking a plurality of impurity regions in a vertical direction.

Selectively, a liner region 148 surrounding each of the photoelectric conversion regions PD may be located within a portion of the first semiconductor substrate 110. The liner region 148 may be located between the pixel isolation structure 140 and the photoelectric conversion region PD and may be a region doped with p-type impurities.

The floating diffusion region FD may be located in an internal region of the first semiconductor substrate 110 adjacent to the front surface 110F of the first semiconductor substrate 110. The floating diffusion region FD may be a region in which charges transferred from the photoelectric conversion region PD are stored. A ground region (not shown) may be located in the internal region of the first semiconductor substrate 110 adjacent to the front surface 110F of the first semiconductor substrate 110. In other embodiments, when two photoelectric conversion regions PD are located within one pixel PX, the floating diffusion region FD may be shared by the two photoelectric conversion regions PD. For example, when one pixel PX includes two photoelectric conversion regions PD, the floating diffusion region FD may be a region in which charges transferred from the two photoelectric conversion regions PD of the pixel PX are stored.

In embodiments, a first transfer gate VTG may be disposed on the front surface 110F of the first semiconductor substrate 110. The first transfer gate VTG may be a transfer gate of a first transfer transistor VTX. Here, the first transfer gate VTG may be a vertical transfer gate.

For example, the first transfer gate VTG may include a first portion and a second portion. The first portion may be disposed on the front surface 110F of the first semiconductor substrate 110, and the second portion may be disposed within a gate trench VTGH extending into the first semiconductor substrate 110 from the front surface 110F of the first semiconductor substrate 110. The second portion may be integrally connected to the first portion, and the second portion may overlap at least a portion of the first portion in a vertical direction.

In FIG. 3, the front surface 110F of the first semiconductor substrate 110 faces downwardly toward the second stack ST2 and the rear surface 110B of the first semiconductor substrate 110 is disposed upwardly, and thus, the first portion may be disposed at a vertical level lower than that of the front surface 110F of the first semiconductor substrate 110. For example, a distance between the first portion and the second stack ST2 in the vertical direction may be less than a distance between the front surface 110F of the first semiconductor substrate 110 and the second stack ST2 in the vertical direction.

In embodiments, a transfer gate insulating layer VTGI may be disposed on an inner wall of the transfer gate trench VTGH. The transfer gate insulating layer VTGI may be located between the first transfer gate VTG and the first semiconductor substrate 110 and may have a relatively uniform thickness.

In embodiments, a second transfer gate DTG may be disposed on the front surface 110F of the first semiconductor substrate 110. The second transfer gate DTG may be a transfer gate of the second transfer transistor DTX. Here, the second transfer gate DTG may be a planar transfer gate.

In embodiments, the first transfer gate VTG and the second transfer gate DTG may be formed using at least one of doped polysilicon, metal, metal silicide, metal nitride, or a metal-containing film.

In embodiments, the first transfer gate VTG may be disposed to be apart from the floating diffusion region FD in a horizontal direction. The second transfer gate DTG may be located between the first transfer gate VTG and the floating diffusion region FD. The second transfer gate DTG may be located to be apart from the first transfer gate VTG by a certain distance in the horizontal direction. Here, the first portion of the first transfer gate VTG and the second transfer gate DTG may be disposed at the same vertical level. However, the first transfer gate VTG may further include a portion at a different vertical level from the second transfer gate DTG, and so the first transfer gate VTG may be thicker or may extend longer in the vertical direction than the second transfer gate DTG. For example, the first transfer gate VTG may extend longer in the vertical direction than it does in a horizontal direction, while the second transfer gate DTG may extend shorter in the vertical direction than it does in a horizontal direction. A transfer gate that extends longer in the vertical direction than in a horizontal direction is described as having a “vertical form,” or may be described as a “vertical gate.” A transfer gate that has a different relationship between the vertical direction and a horizontal direction may have a different form from the vertical form (e.g., a horizontal form). For example, a transfer gate that extends longer in the horizontal direction than in the vertical direction, or that is formed to have a plate shape, may be described as a “planar gate.”

In embodiments, the transfer transistor TX may transfer charges generated in the photoelectric conversion region PD to the floating diffusion region FD. The transfer transistor TX may include a first transfer transistor VTX and a second transfer transistor DTX and may electrically connect the photoelectric conversion region PD to the floating diffusion region FD. In this manner, each of the first transfer transistor VTX and second transfer transistor DTX may electrically connect the photoelectric conversion region PD to the floating diffusion region FD. Components described as electrically connected are arranged so that an electrical signal, voltage, or current can pass therebetween, either through passive connections such as wire lines, or through active connections, such as through transistor active regions and channel regions.

In detail, a channel corresponding to the first transfer gate VTG and a channel corresponding to the second transfer gate DTG may form a charge transfer path FP between the photoelectric conversion region PD and the floating diffusion region FD. The charges generated in the photoelectric conversion region PD may be transferred from the photoelectric conversion region PD to the floating diffusion region FD through the charge transfer path FP.

In embodiments, at least a portion of the second transfer gate DTG may be disposed to overlap the floating diffusion region FD in the vertical direction. For example, the second transfer gate DTG may have a gate spacer layer surrounding a gate electrode. The gate spacer layer and/or a gate electrode may vertically overlap the floating diffusion region FD. Accordingly, the first transfer gate VTG may transfer charges to the floating diffusion region FD through the second transfer gate DTG without contacting the floating diffusion region FD. The first transfer gate VTG may be disposed to be apart from the floating diffusion region FD in the horizontal direction.

In some embodiments of the inventive concept, in the image sensor 100, the floating diffusion region FD is disposed to be apart from the first transfer gate VTG, thereby minimizing the area of the floating diffusion region FD to reduce a capacitor value and resultantly provide high conversion gain. Therefore, image signal sensing may be performed accurately even with a change in small amount of charges in the floating diffusion region FD. In addition, from a noise perspective, random noise (RN), which is noise that appears irregularly on a screen regardless of pixel position, may be improved.

In addition, compared to a comparative example in which a floating diffusion region overlaps a first transfer gate in the vertical direction, the floating diffusion region FD vertically overlapping with the second transfer gate DTG may be reduced. Because the floating diffusion region FD overlapping the second transfer gate DTG is reduced, leakage current (gate induced drain leakage (GIDL)) may be effectively controlled.

The first front surface structure FS1 may be disposed on the front surface 110F of the first semiconductor substrate 110 of the first stack ST1. The first front surface structure FS1 may include a first insulating layer 111 and a second insulating layer 113 disposed on the front surface 110F of the first semiconductor substrate 110. In embodiments, the first insulating layer 111 and the second insulating layer 113 may each include at least one of silicon oxide, silicon nitride, silicon oxynitride, or silicon carbon nitride. For example, the first insulating layer 111 may be silicon oxide, and the second insulating layer 113 may be silicon nitride. Furthermore, each of the first and second insulating layers 111 and 112 may be formed in a stacked structure of a plurality of insulating layers (not shown), and an additional insulating liner (not shown) may be further located between each of the insulating layers.

In embodiments, the first insulating layer 111 may cover the first transfer gate VTG and the second transfer gate DTG disposed on the front surface 110F of the first semiconductor substrate 110. The first front structure FS1 may include a first contact CT1 and a second contact CT2 passing through the first insulating layer 111 and a first interconnection structure 115. The first interconnection structure 115 may be located inside the second insulating layer 113. The first interconnection structure 115 may include a plurality of conductive vias and a plurality of interconnection layers. The first interconnection structure 115 may be electrically connected to each of the first contact CT1, the second contact CT2, the first transfer transistor VTX, and the second transfer transistor DTX.

In embodiments, the first contact CT1 may pass through the first insulating layer 111 and be electrically connected to the first transfer gate VTG and the second transfer gate DTG. The second contact CT2 may pass through the first insulating layer 111 and be electrically connected to the floating diffusion region FD.

In embodiments, the second front surface structure FS2 may be disposed on the front surface 120F of the second semiconductor substrate 120 of the second stack ST2. The second front structure FS2 may include a third insulating layer 121 and a fourth insulating layer 123 disposed on the front surface 120F of the second semiconductor substrate 120.

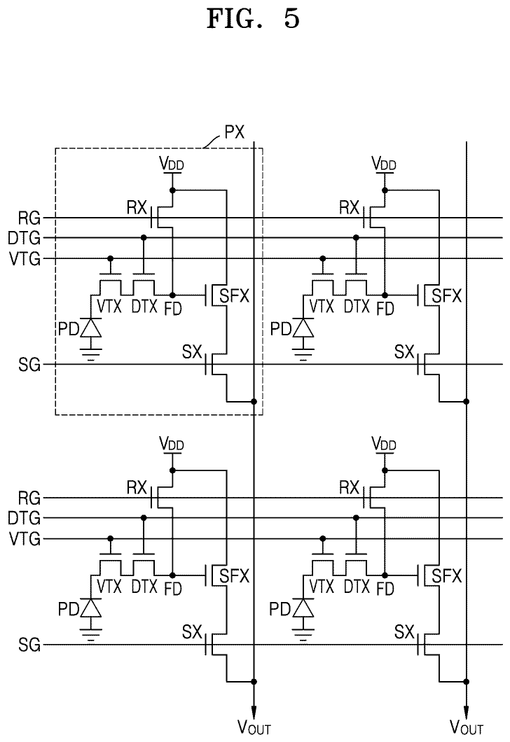

The third insulating layer 121 may cover the pixel transistor PXT disposed on the front surface 120F of the second semiconductor substrate 120. The second front structure FS2 may include a third contact CT3 passing through the third insulating layer 121 and a second interconnection structure 125 located inside the fourth insulating layer 123. The second interconnection structure 125 may include a plurality of conductive vias and a plurality of interconnection layers. The third contact CT3 and the second interconnection structure 125 may be arranged to be electrically connected to the pixel transistor PXT. In embodiments, the pixel transistor PXT may include a reset transistor RX, a select transistor SX, and a source follower transistor SFX (see FIG. 5).

The rear structure BS2 may be disposed on the backside 120B of the second semiconductor substrate 120 of the second stack ST2. The rear structure BS2 may include an insulating layer disposed on the backside 120B of the second semiconductor substrate 120.

A third front surface structure FS3 may be disposed on the front surface 130F of the third semiconductor substrate 130 of the third stack ST3. The third front structure FS3 may include a third interconnection structure 136 and a cover insulating layer 134. The third interconnection structure 136 may include a plurality of conductive vias and a plurality of interconnection layers.

The third interconnection structure 136 may be arranged to be electrically connected to the logic transistor LCT. The third stack ST3 may include a logic transistor LCT disposed on the front surface 130F of the third semiconductor substrate 130, and the logic transistor LCT is connected to the logic gate LCG and source/drain regions LCS may be included.

In embodiments, the first to third contacts CT1, CT2, and CT3 and the first to third interconnection structures 115, 125, and 136 include or are formed of one or more of copper (Cu), aluminum (Al), tungsten (W).), titanium (Ti), titanium nitride (TiN), tantalum (Ta), tantalum nitride (TaN), ruthenium (Ru), and tungsten nitride (WN).

The second front structure FS2 of the second stack ST2 may be arranged to face the first front structure FS1 of the first stack ST1. A first bonding layer BI1 may be located between the first front structure FS1 and the second front structure FS2. The rear structure BS2 of the second stack ST2 may be disposed to face the third front structure FS3 of the third stack ST3. A second bonding layer BI2 may be located between the rear structure BS1 and the third front structure FS3. Each of the first bonding layer BI1 and the second bonding layer BI2 may be formed as a stacked structure of a plurality of insulating layers and may include, for example, at least one of silicon oxide, silicon nitride, silicon oxynitride, or silicon carbon nitride.

In embodiments, the first bonding pad BP1 may be disposed at a boundary between the first stack ST1 and the second stack ST2. The first bonding pad BP1 may be surrounded by the first bonding layer BI1. The first bonding pad BP1 may include an upper pad portion in the first stack ST1 and a lower pad portion in the second stack ST2, and the upper pad portion and the lower pad portion may be arranged to overlap each other in the vertical direction and may be attached to each other. For example, an interface between the upper pad portion and the lower pad portion, for example, a bonding interface, may be located between the first front structure FS1 and the second front structure FS2. The first bonding pad BP1 may include or be copper. For example, the first stack ST1 and the second stack ST2 may be stacked using a metal-oxide hybrid bonding method.

In embodiments, the second bonding pad BP2 may be disposed at a boundary between the second stack ST2 and the third stack ST3. The second bonding pad BP2 may be surrounded by the second bonding layer BI2. The second stack ST2 and the third stack ST3 may be stacked using a metal-oxide hybrid bonding method. The second bonding pad BP2 may include or be copper.

FIG. 5 is an equivalent circuit diagram of a pixel PX of an image sensor according to embodiments.

Referring to FIG. 5, a plurality of pixels PX may be arranged in a matrix form. Each of the pixels PX may include a first transfer transistor VTX, a second transfer transistor DTX, and pixel transistors. Here, the pixel transistors may include a reset transistor RX, a select transistor SX, and a source follower transistor SFX. The reset transistor RX may include a reset gate RG, the select transistor SX may include a select gate SG, the first transfer transistor VTX may include a first transfer gate VTG, and the second transfer transistor DTX may include a second transfer gate DTG.

Each of the pixels PX may further include a photoelectric conversion region PD and a floating diffusion region FD. The photoelectric conversion region PD may correspond to the photoelectric conversion region PD described with reference to FIGS. 1 to 4. The photoelectric conversion region PD may generate and accumulate photocharges in proportion to the amount of light incident from the outside, and a photodiode, a photo transistor, a photogate, a pinned photodiode PPD, and combinations thereof may be used.

The first transfer gate VTG and the second transfer gate DTG may transmit charges generated in the photoelectric conversion region PD to the floating diffusion region FD. In detail, the charges generated in the photoelectric conversion region PD may be transmitted to the floating diffusion region FD through a channel of the first transfer gate VTG and a channel of the second transfer gate DTG. The channel of the first transfer gate VTG and the channel of the second transfer gate DTG may form a charge transfer path (FP, see FIG. 4) between the photoelectric conversion region PD and the floating diffusion region FD. The charges generated in the photoelectric conversion region PD may be transferred from the photoelectric conversion region PD to the floating diffusion region FD through the charge transfer path FP. The floating diffusion region FD may receive the charges generated in the photoelectric conversion region PD and store them cumulatively. The source follower transistor SFX may be controlled according to the amount of photocharges accumulated in the floating diffusion region FD.

The reset transistor RX may periodically reset the charges accumulated in the floating diffusion region FD. A drain electrode of the reset transistor RX is connected to the floating diffusion region FD, and a source electrode thereof is connected to a power supply voltage VDD. When the reset transistor RX is turned on, the power supply voltage VDD connected to the source electrode of the reset transistor RX is transferred to the floating diffusion region FD. When the reset transistor RX is turned on, the charges accumulated in the floating diffusion region FD may be discharged and the floating diffusion region FD may be reset.

The source follower transistor SFX is connected to a current source (not shown) located outside the pixels PX and functions as a source follower buffer amplifier, amplifies a change in potential in the floating diffusion region FD, and outputs the amplified change in potential to an output line VOUT.

The select transistor SX may select a plurality of pixels PX on a row basis, and an output voltage generated by the source follower transistor SFX when the select transistor SX is turned on may be transferred to the output line VOUT.

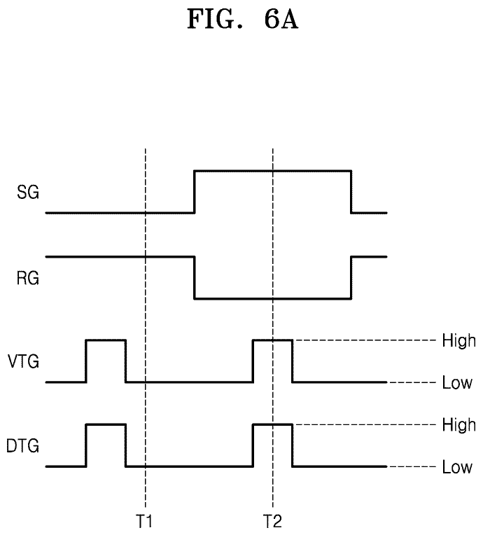

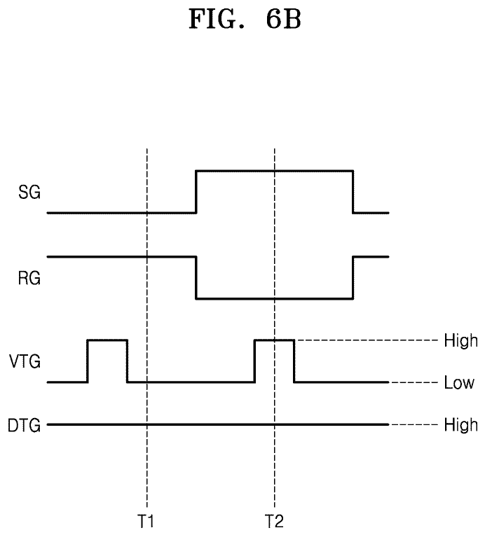

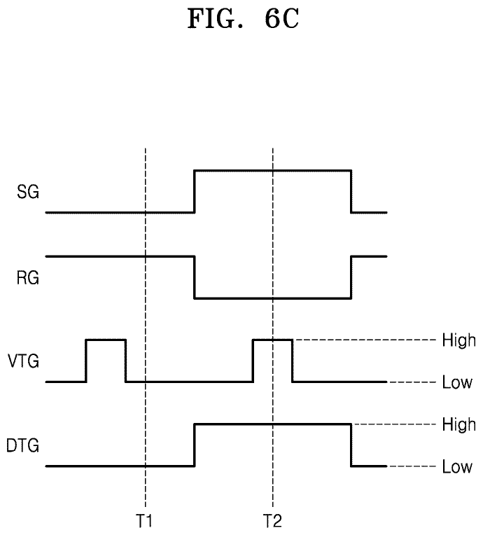

FIGS. 6A to 6C are timing diagrams illustrating an operation of the unit pixel of FIG. 5.

Referring to FIG. 6A, at time T1, a reset signal RG provided to the unit pixel PX is at a high level, and a select signal SG, a first transfer signal VTG, and a second transfer signal DTG are at a low level. Accordingly, the reset transistor RX may be turned on, and the charges existing in the floating diffusion region FD and the photoelectric conversion region PD may be drained to the power supply voltage VDD terminal to reset the floating diffusion region FD.

In embodiments, at time T1, the first transfer transistor VTX and the second transfer transistor DTX may be turned off. At a time point at which the first transfer transistor VTX and the second transfer transistor DTX are turned off, an absolute value of a voltage applied to the first transfer gate VTG may be greater than an average value of a voltage applied to the second transfer gate DTG. For example, a negative voltage (e.g., −1.4 V) may be applied to the first transfer gate VTG of the first transfer transistor VTX. A ground voltage (0 V) may be applied to the second transfer gate DTG of the second transfer transistor DTX.

In the image sensor 100 according to aspects of the inventive concept, by disposing the second transfer gate DTG between the first transfer gate VTG and the floating diffusion region FD and applying a ground voltage to the second transfer gate DTG, a voltage difference between the floating diffusion region FD and the second transfer gate DTG may be reduced. As the voltage difference between the floating diffusion region FD and the second transfer gate DTG is reduced, the leakage current GIDL may be effectively controlled. In addition, by applying a ground voltage to the second transfer gate DTG, the problem of the comparative example in which a dark current occurs when applying a ground voltage to the vertical transfer gate may be addressed or solved.

At time T2, the reset signal RG provided to the unit pixel PX is at a low level, and the select signal SG, the first transfer signal VTG, and the second transfer signal DTG are at a high level. For example, a positive voltage (e.g., 2.2 V) may be applied to the first transfer gate VTG and the second transfer gate DTG. Accordingly, the charges accumulated in the photoelectric conversion region PD may move to the floating diffusion region FD through the first transfer transistor VTX and the second transfer transistor DTX.

The operation of the unit pixel PX is not limited thereto, and the unit pixel PX may operate in various manners as needed. For example, referring to FIG. 6B, the second transfer signal DTG may be constantly maintained at a high level to turn on and operate the second transfer transistor DTX constantly. In another embodiment, referring to FIG. 6C, the second transfer signal DTG may match an operation signal of the select signal SG to operate the unit pixel PX. When the unit pixel PX operates according to FIG. 6B or 6C, a separate design for the operation of the second transfer signal DTG may not be necessary.

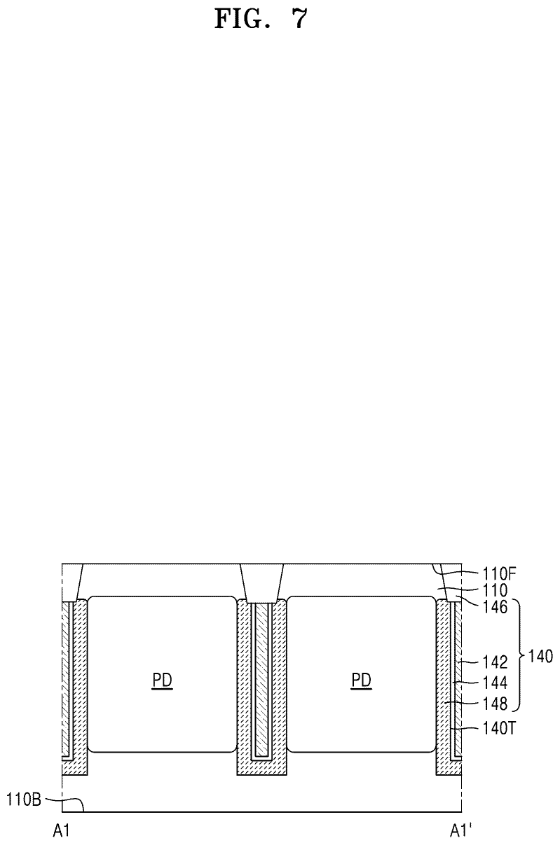

FIGS. 7 to 13 are cross-sectional views illustrating a method of manufacturing the image sensor 100 according to embodiments.

Referring to FIG. 7, the first semiconductor substrate 110 having the front surface 110F and the rear surface 110B that are opposite to each other is prepared.

Thereafter, a mask pattern (not shown) is formed on the front surface 110F of the first semiconductor substrate 110, and a pixel trench 140T may be formed within the first semiconductor substrate 110 using the mask pattern as an etch mask. The pixel trench 140T may have a certain depth from the front surface 110F and may be formed in a matrix form in a plan view.

Thereafter, the insulating liner 144 may be conformally formed on the inner wall of the pixel trench 140T by a chemical vapor deposition (CVD) process or an atomic layer deposition (ALD) process, for example. Thereafter, the conductive layer 142 that fills the inner wall of the pixel trench 140T may be formed on the insulating liner 144. The conductive layer 142 may include at least one of doped polysilicon, metal, metal silicide, metal nitride, or a metal-containing film.

Thereafter, an upper portion of the conductive layer 142 may be removed by an etch-back process or the like so that an upper surface of the conductive layer 142 has a level lower than that of an upper surface of the front surface 110F of the first semiconductor substrate 110, an insulating layer (not shown) is filled to fill the entrance of the pixel trench 140T, and the insulating layer may be removed (e.g., planarized) so that the upper surface of the first semiconductor substrate 110 is exposed, thereby leaving the upper insulating layer 146 within the entrance of the pixel trench 140T.

Thereafter, selectively, the liner region 148 surrounding each of the photoelectric conversion regions PD may be formed within a portion of the first semiconductor substrate 110. The liner region 148 may be located between the pixel isolation structure 140 and the photoelectric conversion region PD and may be a region doped with p-type impurities.

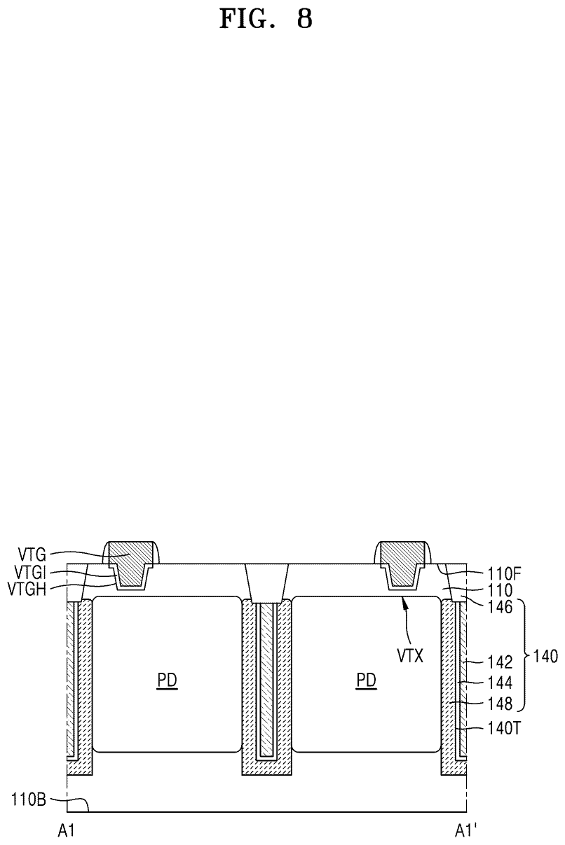

Referring to FIG. 8, the first transfer gate VTG may be formed in a resultant structure of FIG. 7. A mask pattern (not shown) may be formed on the front surface 110F of the first semiconductor substrate 110, and the transfer gate trench VTGH may be formed within the first semiconductor substrate 110 by using the mask pattern as an etch mask. A portion of the first semiconductor substrate 110 may be etched to form the transfer gate trench VTGH.

Thereafter, the transfer gate insulating layer VTGI may be formed to conformally cover the inner wall of the transfer gate trench VTGH. Thereafter, a transfer gate electrode layer (not shown) may be formed to cover the inside of the transfer gate trench VTGH and the front surface 110F of the first semiconductor substrate 110, and a portion of the transfer gate electrode layer may be removed to form the first transfer gate VTG.

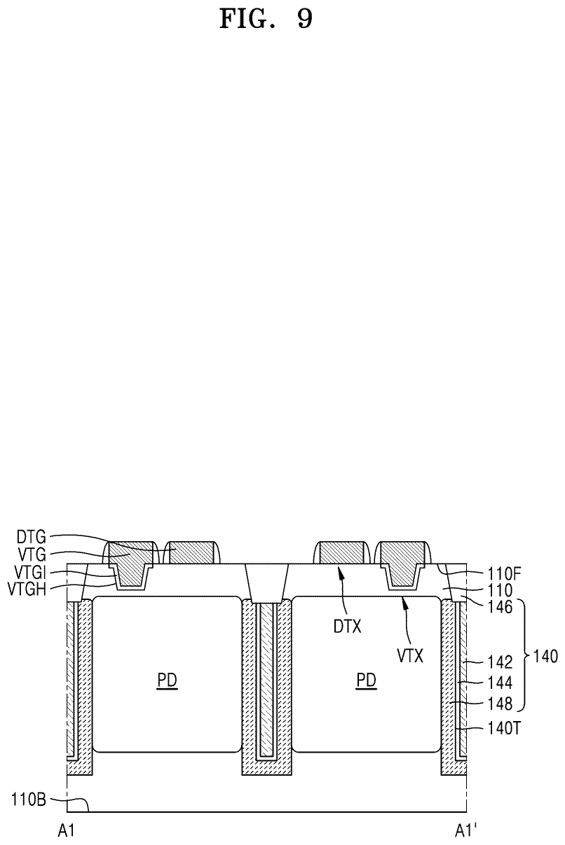

Referring to FIG. 9, the second transfer gate DTG may be formed in a resultant structure of FIG. 8. The second transfer gate DTG may be formed on the front surface 110F of the first semiconductor substrate 110. Here, the second transfer gate DTG may be formed to be apart from the first transfer gate VTG by a certain distance in the horizontal direction. For example, the second transfer gate DTG may be at the same vertical level as that of the first portion of the first transfer gate VTG.

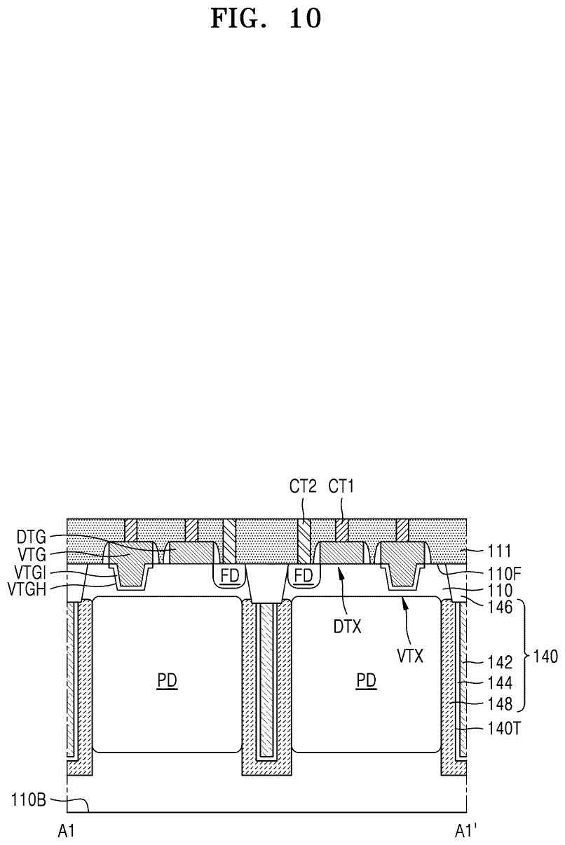

Referring to FIG. 10, the floating diffusion region FD may be formed from the front surface 110F of the first semiconductor substrate 100 through an ion implantation process. For example, the floating diffusion region FD may be formed by doping n-type impurities.

Thereafter, the first insulating layer 111 covering the first transfer gate VTG, the second transfer gate DTG, and the front surface 110F of the first semiconductor substrate 110 may be formed, and the first contact CT1 and the second contact CT2 passing through the first insulating layer 111 may be formed. In embodiments, the first contact CT1 may pass through the first insulating layer 111 and be electrically connected to the first transfer gate VTG and the second transfer gate DTG. The second contact CT2 may pass through the first insulating layer 111 and be electrically connected to the floating diffusion region FD or a ground region (not shown).

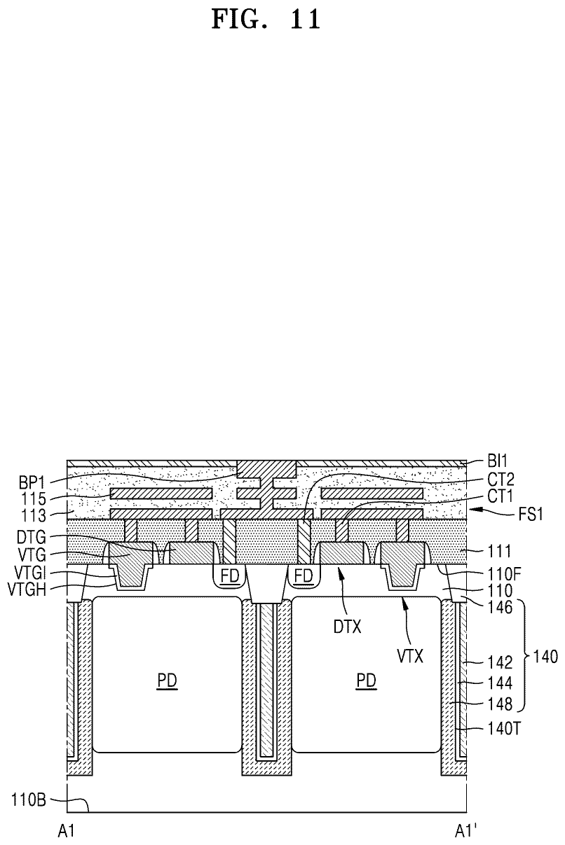

Referring to FIG. 11, in a resultant structure of FIG. 10, the second insulating layer 113 and the first interconnection structure 115 may be formed on the first insulating layer 111. The first interconnection structure 115 may be located inside the second insulating layer 113. The first interconnection structure 115 may include a plurality of conductive vias and a plurality of interconnection layers. The first interconnection structure 115 may be electrically connected to each of the first contact CT1, the second contact CT2, the first transfer transistor VTX, and the second transfer transistor DTX. Subsequently, the first bonding layer BI1 and the first bonding pad BP1 may be formed on the second insulating layer 113.

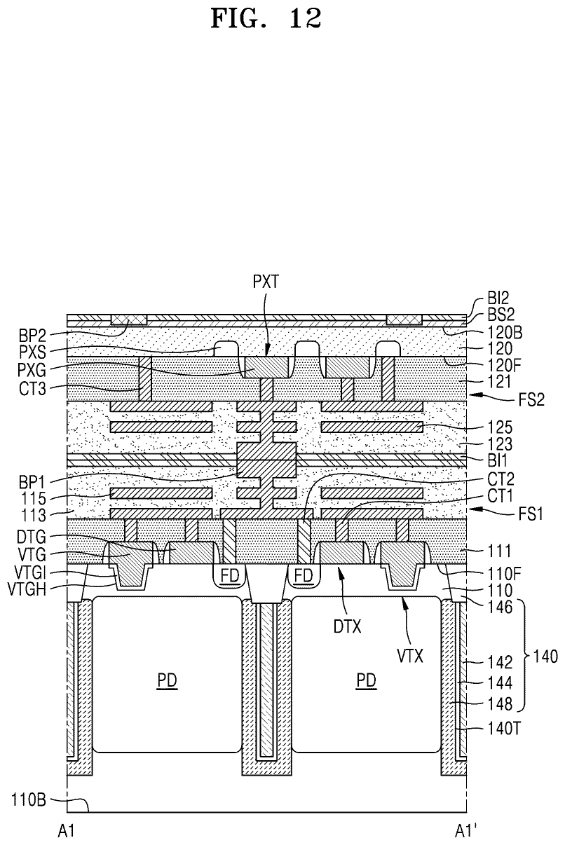

Referring to FIG. 12, in a resultant structure of FIG. 11, the second stack ST2 (see FIG. 3) may be attached to the first stack ST1 (see FIG. 3).

The second stack ST2 may include the second semiconductor substrate 120 having the front surface 120F and the rear surface 120B, the pixel transistor PXT and the second front structure FS2 disposed on the front surface 120F of the second semiconductor substrate 120, and the rear structure BS2 disposed on the rear surface 120B of the second semiconductor substrate 120.

Thereafter, the second stack ST2 may be attached to the first stack ST1 with the first bonding layer BI1 therebetween. Here, the second front structure FS2 of the second stack ST2 may be attached to face the first front structure FS1 of the first stack ST1. With the pixel transistor PXT, the second front structure FS2, and the rear structure BS2 formed on the second semiconductor substrate 120, the second stack ST2 may be attached to the first stack ST1.

Here, the first bonding pad BP1 may include an upper pad portion in the first stack ST1 and a lower pad portion in the second stack ST2, and the upper pad portion and the lower pad portion may be arranged to overlap each other in the vertical direction and be attached to each other. For example, the first stack ST1 and the second stack ST2 may be stacked using a metal-oxide hybrid bonding method. Subsequently, the second bonding layer B12 and the second bonding pad BP2 may be formed on the rear structure BS2.

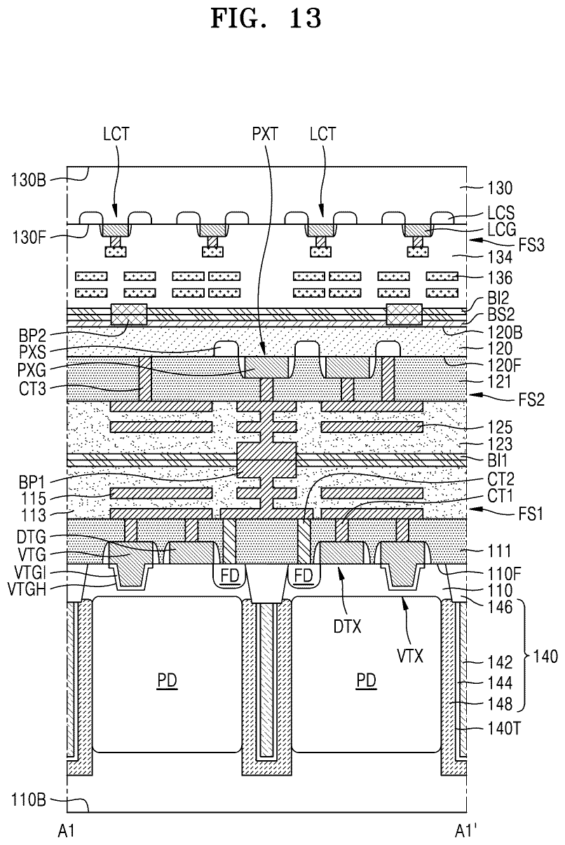

Referring to FIG. 13, in a resultant structure of FIG. 12, the third stack ST3 (see FIG. 3) may be attached to the second stack ST2 (see FIG. 3).

The third stack ST3 may include the third semiconductor substrate 130 having the front surface 130F and the logic transistor LCT and the third front structure FS3 disposed on the front surface 130F of the third semiconductor substrate 130.

Thereafter, the third stack ST3 may be attached to the second stack ST2 with the second bonding layer B12 therebetween. Here, the third stack ST3 may be attached so that the third front structure FS3 of the third stack ST3 faces the rear structure BS2 of the second stack ST2. With the logic transistor LCT formed on the third semiconductor substrate 120, the third stack ST3 may be attached to the second stack ST2.

Here, the second bonding pad BP2 may include an upper pad portion in the second stack ST2 and a lower pad portion in the third stack ST3, and the upper pad portion and the lower pad portion may be arranged to overlap each other in the vertical direction and be attached to each other. For example, the second stack ST2 and the third stack ST3 may be stacked using a metal-oxide hybrid bonding method.

Referring back to FIG. 3, the stacked structure may be turned over so that the rear surface 110B of the first semiconductor substrate 110 faces upwardly. Thereafter, a portion of the first semiconductor substrate 110 may be removed from the rear surface 110B of the first semiconductor substrate 110 through a planarization process, such as a CMP process or an etch-back process so that the upper surface of the pixel isolation structure 140 (e.g., an end portion adjacent to the rear surface 110B of the first semiconductor substrate 110) is exposed.

Although not shown, a rear insulating layer (not shown) may be formed on the rear surface 110B of the first semiconductor substrate 110. The rear insulating layer may include metal oxide and may function as a negative charge fixing layer. Thereafter, the image sensor 100 may be completed by forming a color filter CF and a microlens ML on the rear surface 110B of the first semiconductor substrate 110 in the active pixel region APR.

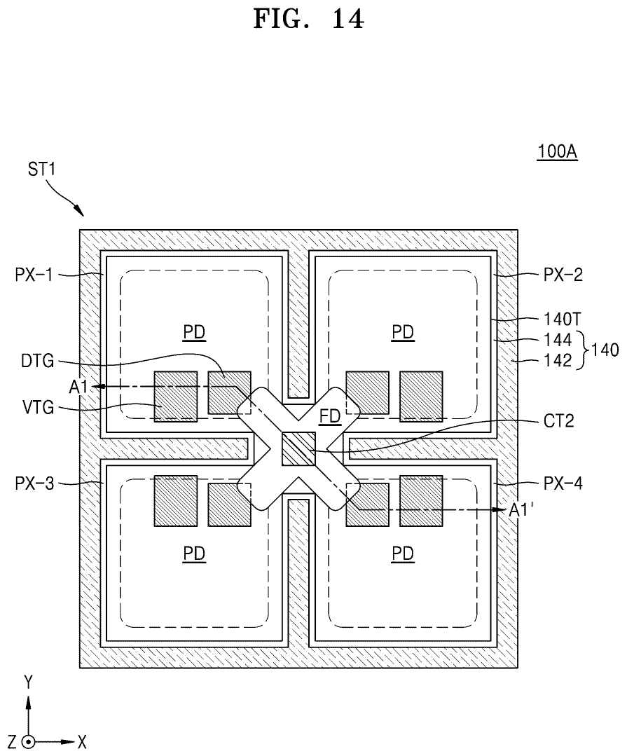

FIG. 14 is a layout diagram illustrating an image sensor 100A according to embodiments.

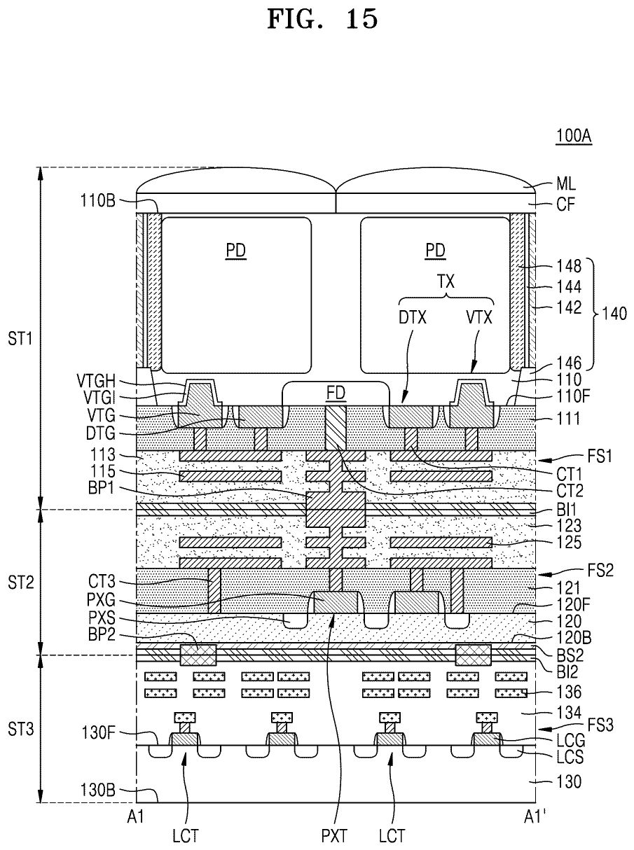

FIG. 15 is a cross-sectional view taken along line′ in FIG. 14.

Referring to FIGS. 14 and 15, the floating diffusion region FD may be shared by the first to fourth pixels PX-1 to PX-4. The pixel isolation structure 140 may not be located in a portion of the first semiconductor substrate 110 that vertically overlaps the floating diffusion region FD. In embodiments, the pixel isolation structure 140 may not be located in a region adjacent to the center of the first to fourth pixels PX-1 to PX-4. The region in which the pixel isolation structure 140 is not disposed may be referred to as a first region.

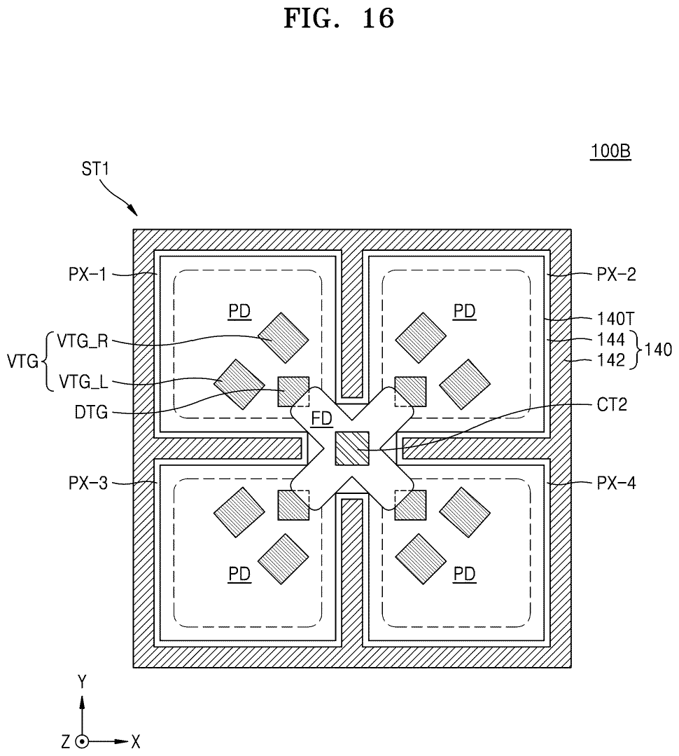

In embodiments, the first region may overlap the floating diffusion region FD in the vertical direction (a Z-direction). For example, the first region may include a silicon region doped with P-type impurities. In embodiments, the first region may not overlap the photoelectric conversion region PD in the vertical direction (the Z-direction). FIG. 16 is a layout diagram illustrating an image sensor 100B according to embodiments.

Referring to FIG. 16, the first transfer gate VTG may be a dual-type transfer gate. For example, two first transfer gates VTG may be located within one pixel. For example, the first transfer gate VTG may include a pair of first transfer gates VTG_L and VTG_R arranged to be apart from each other. In some embodiments, as shown in FIG. 16, the pair of first transfer gates VTG_L and VTG_R may be arranged to have the same distance from the second transfer gate DTG in the horizontal direction. In addition, the pair of first transfer gates VTG_L and VTG_R may be arranged to have the same distance from the floating diffusion region FD in the horizontal direction.

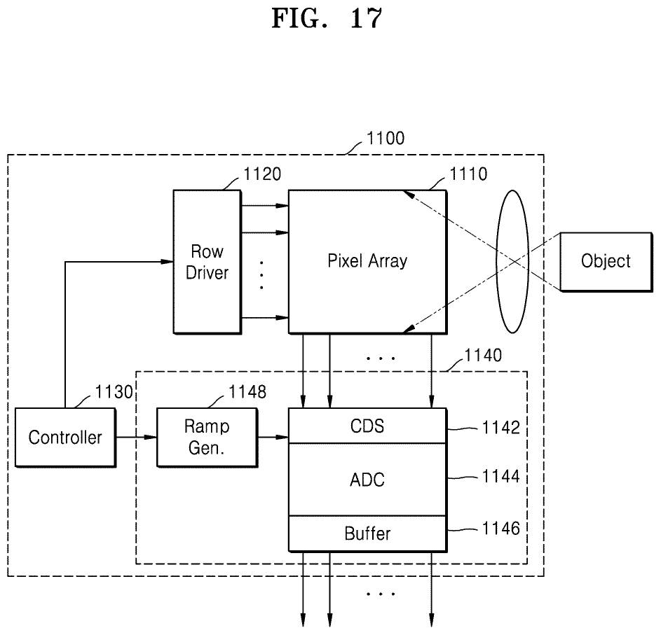

FIG. 17 is a block diagram illustrating a configuration of an image sensor 1100 according to an embodiment.

Referring to FIG. 17, the image sensor 1100 may include a pixel array 1110, a controller 1130, a row driver 1120, and a pixel signal processor 1140. The image sensor 1100 includes at least one of the image sensors 100 and 100A described above with reference to FIGS. 1 to 13.

The pixel array 1110 may include a plurality of unit pixels arranged two-dimensionally, and each unit pixel may include a photoelectric conversion device. The photoelectric conversion device may absorb light to generate charges, and an electrical signal (an output voltage) according to the generated charges may be provided to the pixel signal processor 1140 through a vertical signal line. The unit pixels included in the pixel array 1110 may provide one output voltage at a time in row units, and accordingly, the unit pixels belonging to one row of the pixel array 1110 may be simultaneously activated by a select signal output from the row driver 1120. Unit pixels belonging to a selected row may provide an output voltage according to the absorbed light to an output line of a corresponding column.

The controller 1130 may cause the pixel array 1110 to absorb light and accumulate charges or temporarily store the accumulated charges and may control the row driver 1120 to output an electrical signal according to the stored charges to the outside of the pixel array 1110. In addition, the controller 1130 may control the pixel signal processor 1140 to measure the output voltage provided from the pixel array 1110.

The pixel signal processor 1140 may include a correlated double sampler (CDS) 1142, an analog-to-digital converter (ADC) 1144, and a buffer 1146. The CDS 1142 may sample and hold the output voltage provided from the pixel array 1110. The CDS 1142 may double-sample a specific noise level and a level according to the generated output voltage and output a level corresponding to a difference therebetween. In addition, the CDS 1142 may receive ramp signals generated by a ramp signal generator (ramp gen.) 1148, compare the ramp signals with each other, and output a comparison result.

The ADC 1144 may convert an analog signal corresponding to the level received from the CDS 1142 into a digital signal. The buffer 1146 may latch a digital signal, and the latched signal may be sequentially output to the outside of the image sensor 1100 and transferred to an image processor (not shown).

While the inventive concept has been particularly shown and described with reference to embodiments thereof, it will be understood that various changes in form and details may be made therein without departing from the spirit and scope of the following claims.

What is claimed is:

1. An image sensor, comprising:
a first semiconductor substrate;
a photoelectric conversion region located within the first semiconductor substrate;
a floating diffusion region located within the first semiconductor substrate and storing charges transferred from the photoelectric conversion region;
a first transfer transistor including a first transfer gate having a vertical form and disposed to be apart from the floating diffusion region in a horizontal direction and electrically connecting the photoelectric conversion region to the floating diffusion region; and
a second transfer transistor including a second transfer gate located between the first transfer gate and the floating diffusion region and having a form different from the form of the first transfer gate and electrically connecting the first transfer transistor to the floating diffusion region.

2. The image sensor of claim 1, wherein:
the first transfer gate includes:
a first portion disposed on a first surface of the first semiconductor substrate; and
a second portion integrally connected to the first portion and extending into the first semiconductor substrate in a vertical direction.

3. The image sensor of claim 2, wherein the second transfer gate is disposed at the same vertical level as the first portion of the first transfer gate.

4. The image sensor of claim 2, wherein the first transfer transistor further includes a transfer gate insulating layer disposed on an inner wall of a transfer gate trench extending from the first surface of the first semiconductor substrate into the first semiconductor substrate and located between the first semiconductor substrate and the second portion of the first transfer gate.

5. The image sensor of claim 2, wherein the second transfer gate is disposed on the first surface of the first semiconductor substrate.

6. The image sensor of claim 1, wherein at least a portion of the second transfer gate overlaps the floating diffusion region in a vertical direction.

7. The image sensor of claim 1, configured such that, with the first transfer transistor and the second transfer transistor turned off, an absolute value of a voltage applied to the first transfer gate is greater than an absolute value of a voltage applied to the second transfer gate.

8. The image sensor of claim 1, configured such that, with the first transfer transistor turned off, a negative voltage is applied to the first transfer gate and with the second transfer transistor turned off, a ground voltage is applied to the second transfer gate.

9. The image sensor of claim 1, wherein the first transfer gate is one of a pair of first transfer gates, and the pair of first transfer gates are each arranged to be equally apart from the second transfer gate in the horizontal direction.

10. An image sensor, comprising:
a first semiconductor substrate including a first surface and a second surface opposite to the first surface;
a photoelectric conversion region located within the first semiconductor substrate;
a floating diffusion region located within the first semiconductor substrate and storing charges transferred from the photoelectric conversion region;
a first transfer gate in the form of a vertical gate disposed to be apart from the floating diffusion region in a horizontal direction and extending into the first semiconductor substrate in a vertical direction; and
a second transfer gate in the form of a planar gate located between the first transfer gate and the floating diffusion region on the first surface of the first semiconductor substrate.

11. The image sensor of claim 10, wherein the second transfer gate is located to be apart from the first transfer gate in the horizontal direction.

12. The image sensor of claim 10, wherein the second transfer gate is disposed at the same vertical level as a first portion of the first transfer gate disposed on the first surface of the first semiconductor substrate.

13. The image sensor of claim 10, wherein at least a portion of the second transfer gate is disposed to overlap the floating diffusion region in the vertical direction.

14. The image sensor of claim 10, configured such that, when a negative voltage is applied to the first transfer gate, a ground voltage is applied to the second transfer gate.

15. An image sensor, comprising:
a first stack including a first semiconductor substrate including a first surface and a second surface opposite to the first surface, a photoelectric conversion region located within the first semiconductor substrate, a floating diffusion region located within the first semiconductor substrate and storing charges transferred from the photoelectric conversion region, a first transfer gate having a vertical form and disposed to be apart from the floating diffusion region in a horizontal direction, and a second transfer gate located between the first transfer gate and the floating diffusion region and having a form different from the form of the first transfer gate;
a second stack including a second semiconductor substrate including a first surface and a second surface opposite to the first surface and a pixel gate disposed on the first surface or the second surface of the second semiconductor substrate and electrically connected to the floating diffusion region; and
a third stack attached to the second stack, the third stack including a logic transistor providing a signal to the pixel gate, the first transfer gate, and the second transfer gate.

16. The image sensor of claim 15, wherein:
the first transfer gate includes:
a first portion disposed on the first surface of the first semiconductor substrate; and
a second portion integrally connected to the first portion and extending into the first semiconductor substrate in a vertical direction.

17. The image sensor of claim 16, wherein the second transfer gate is disposed on the first surface of the first semiconductor substrate and disposed at the same vertical level as the first portion of the first transfer gate.

18. The image sensor of claim 15, wherein at least a portion of the second transfer gate is disposed to overlap the floating diffusion region in a vertical direction.

19. The image sensor of claim 15, configured such that, when a negative voltage is applied to the first transfer gate, a ground voltage is applied to the second transfer gate.

20. The image sensor of claim 15, wherein the pixel gate is disposed at a different vertical level from the second transfer gate.
